(19) United States
(12) Patent Application Publication
(10) Pub. No.: US 2024/0375940 A1
(43) Pub. Date: Nov. 14, 2024

(54) RESONANCE DEVICE AND RESONANCE DEVICE MANUFACTURING METHOD

(71) Applicant: Murata Manufacturing Co., Ltd., Nagaokakyo-shi (JP)

(72) Inventor: Masakazu FUKUMITSU, Nagaokakyo-shi (JP)

(21) Appl. No.: 18/780,926

(22) Filed: Jul. 23, 2024

Related U.S. Application Data
(63) Continuation of application No. PCT/JP2022/040171, filed on Oct. 27, 2022.

(30) Foreign Application Priority Data
Mar. 11, 2022 (JP) 2022-037702

(51) Int. Cl. B81B 7/00; B81C 1/00; H03H 9/15

(52) U.S. Cl. CPC B81B 7/0038; B81C 1/00285; H03H 9/15; B81B 2201/0271; B81B 2203/0315; B81B 2203/04; B81C 2201/0176; B81C 2201/019; H03H 2009/155

(57) ABSTRACT

A resonance device that includes: a first substrate which includes a first silicon substrate and a resonator; a second substrate arranged on a side of the resonator opposite to the first silicon substrate; and a bonding portion bonding the first substrate and the second substrate to each other so as to seal a vibration space of the resonator. The resonator has a silicon film on a surface thereof facing the first silicon substrate. The silicon film is directly bonded to the first silicon substrate in an entire circumferential region surrounding the vibration space in a plan view of the first substrate.

### CROSS REFERENCE TO RELATED APPLICATIONS

The present application is a continuation of International application No. PCT/JP2022/040171, filed Oct. 27, 2022, which claims priority to Japanese Patent Application No. 2022-037702, filed Mar. 11, 2022, the entire contents of each of which are incorporated herein by reference.

### TECHNICAL FIELD

The present disclosure relates to a resonance device and a resonance device manufacturing method.

### BACKGROUND ART

Conventionally, resonance devices manufactured using the micro electro mechanical systems (MEMS) technology have been widely used. The device is formed by bonding a second substrate to a first substrate including a resonator, for example.
Patent Document 1: U.S. Pat. No. 10,800,650

For example, Patent Document 1 discloses MEMS that include a silicon handle wafer; a bottom silicon oxide provided on the silicon handle wafer; a silicon device layer provided on the bottom silicon oxide; a middle silicon oxide provided on the silicon device layer; a lid layer silicon provided on the middle silicon oxide; a first barrier that blocks hydrogen and helium that use the bottom silicon oxide as an ingress path; and a second barrier that blocks hydrogen and helium that use the middle silicon oxide as an ingress path; and in which the first barrier penetrates through the bottom silicon oxide, the second barrier penetrates through the middle silicon oxide, and the first barrier and the second barrier are formed so as to surround a MEMS cavity formed in the silicon device layer.

### SUMMARY OF THE DISCLOSURE

However, when a helium ingress path is blocked by a barrier penetrating through a silicon oxide as in Patent Document 1, the ingress of helium sometimes cannot be sufficiently blocked due to a formation defect of the barrier.

The present disclosure has been made in view of such circumstances and an object of the present disclosure is to provide a resonance device and a resonance device manufacturing method that can achieve suppression of helium gas ingress.

A resonance device according to an aspect of the present disclosure includes: a first substrate which includes a first silicon substrate and a resonator; a second substrate arranged on a side of the resonator opposite to the first silicon substrate; and a bonding portion bonding the first substrate and the second substrate to each other so as to seal a vibration space of the resonator. The resonator has a silicon film on a surface thereof facing the first silicon substrate. The silicon film is directly bonded to the first silicon substrate in an entire circumferential region surrounding the vibration space in a plan view of the first substrate.

A resonance device manufacturing method according to another aspect of the present disclosure includes: forming a first substrate by directly bonding a first silicon substrate and silicon film of a resonator to each other; and bonding the first substrate and the second substrate to each other so as to seal a vibration space of the resonator. The silicon film is in an entire circumferential region surrounding the vibration space in a plan view of the first substrate.

According to the present disclosure, the resonance device and resonance device manufacturing method that can achieve suppression of helium gas ingress can be provided.

### BRIEF DESCRIPTION OF THE DRAWINGS

FIG. 1 is a perspective view schematically illustrating a configuration of a resonance device according to a first embodiment.

FIG. 2 is an exploded perspective view schematically illustrating the configuration of the resonance device according to the first embodiment.

FIG. 3 is a plan view schematically illustrating the configuration of the resonance device according to the first embodiment.

FIG. 4 is a sectional view schematically illustrating the configuration of the resonance device according to the first embodiment.

FIG. 5 is a flowchart showing a resonance device manufacturing method according to an embodiment of the present disclosure.

FIG. 6 is a sectional view schematically illustrating a configuration of a resonance device according to a second embodiment.

FIG. 7 is a sectional view schematically illustrating a configuration of a resonance device according to a third embodiment.

FIG. 8 is a sectional view schematically illustrating a configuration of a resonance device according to a fourth embodiment.

FIG. 9 is a sectional view schematically illustrating a configuration of a resonance device according to a fifth embodiment.

FIG. 10 is a sectional view schematically illustrating a configuration of a resonance device according to a sixth embodiment.

FIG. 11 is a sectional view schematically illustrating a configuration of a resonance device according to a seventh embodiment.

### DESCRIPTION OF THE PREFERRED EMBODIMENTS

Embodiments according to the present disclosure will be described below with reference to the accompanying drawings. The drawings of the embodiments are examples, and the dimensions and shapes of respective components are schematic, and the technical scope of the disclosure of the present application should not be limitedly interpreted to the embodiments.

### First Embodiment

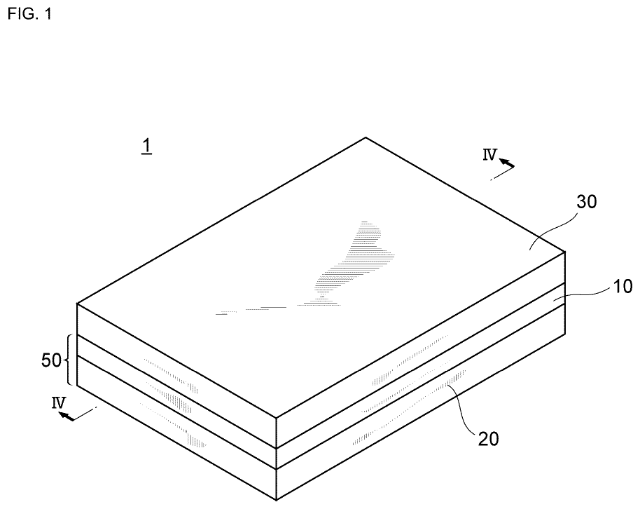

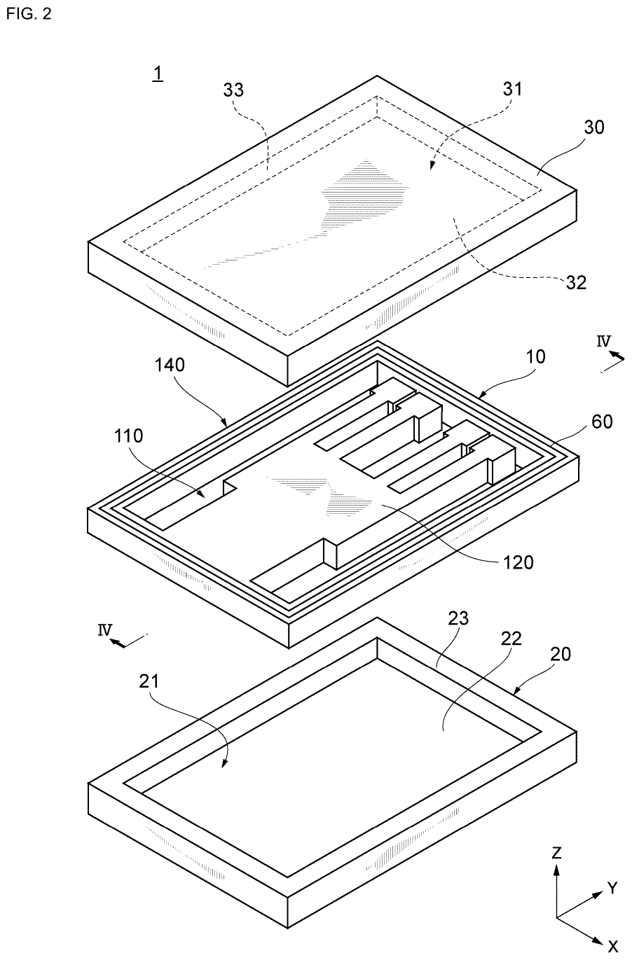

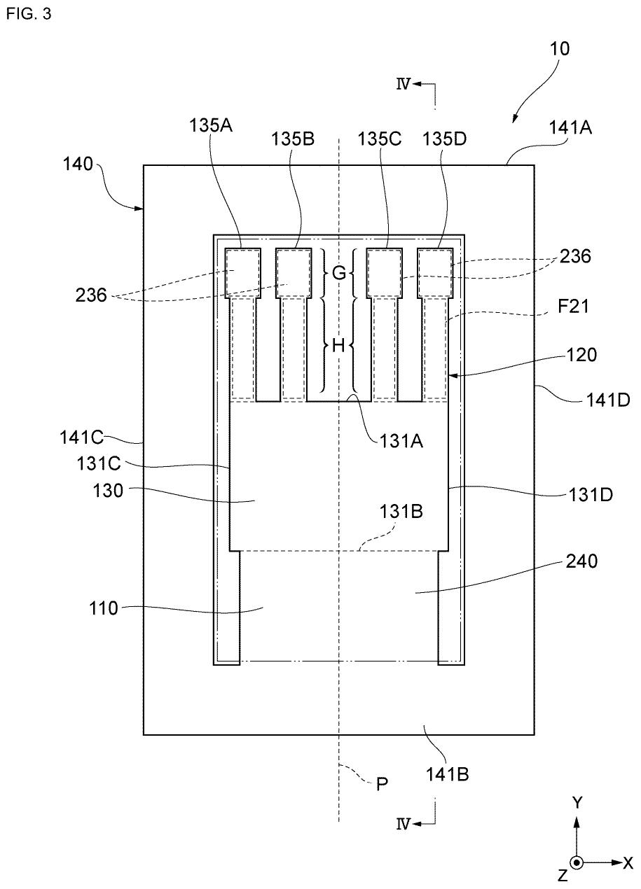

A configuration of a resonance device 1 according to a first embodiment of the present disclosure will be described with reference to FIG. 1, FIG. 2, and FIG. 3. FIG. 1 is a perspective view schematically illustrating the configuration of the resonance device according to the present embodiment. FIG. 2 is an exploded perspective view schematically illustrating a configuration of a resonator according to the first embodiment. FIG. 3 is a plan view schematically illustrating the configuration of the resonance device according to the first embodiment.

Each drawing is accompanied by an orthogonal coordinate system consisting of an X axis, a Y axis, and a Z axis for convenience in order to clarify the relationship between the drawings and to help understanding of the positional relationship of each member. The directions parallel to the X axis, Y axis, and Z axis will be referred to as the X-axis direction, Y-axis direction, and Z-axis direction, respectively. Further, for convenience, the positive direction of the Z axis (the direction of the arrow on the Z axis) is referred to as “upper”, and the negative direction of the Z axis (the direction opposite to the direction of the arrow on the Z axis) is referred to as “lower”. A plane defined by the X axis and the Y axis is an XY plane, and the same applies to a YZ plane and a ZX plane.

The resonance device 1 includes a lower lid 20, a resonator 10 (hereinafter, the lower lid 20 and the resonator 10 will be sometimes collectively referred to as a “MEMS substrate 50”), an upper lid 30, and a bonding portion 60. The MEMS substrate 50, the bonding portion 60, and the upper lid 30 are laminated in this order to be structured. The resonator 10 and the lower lid 20 are directly bonded to each other, and the resonator 10 and the upper lid 30 are bonded by the bonding portion 60. The MEMS substrate 50 corresponds to an example of a “first substrate” of the present disclosure, and the upper lid 30 corresponds to an example of a “second substrate” of the present disclosure.

Each component of the resonance device 1 will be described below. In the following description, the side of the resonance device 1 on which the upper lid 30 is provided is referred to as upper (or front), and the side on which the lower lid 20 is provided is referred to as lower (or back).

The resonator 10 is a piezoelectric vibrating element manufactured using the MEMS technology. The resonator 10 vibrates in an out-of-plane bending vibration mode. The frequency band of the resonator 10 is, for example, from 1 kHz to 1 MHz inclusive.

The resonator 10 includes a holding arm 110, a vibrating portion 120, and a holding portion 140. The resonator 10 is formed to be, for example, substantially plane-symmetrical to a virtual plane P which is parallel to the YZ plane. Specifically, each of the holding arm 110, the vibrating portion 120, and the holding portion 140 is formed to be substantially plane-symmetrical to the virtual plane P.

The holding arm 110 connects the vibrating portion 120 and the holding portion 140 with each other, and holds the vibrating portion 120 so that the vibrating portion 120 can vibrate. The holding arm 110 is provided between the vibrating portion 120 and the holding portion 140 in plan view of the XY plane (hereinafter, merely referred to as “in plan view”). The holding arm 110 is composed of one arm portion, which extends in the Y-axis direction. One end of the holding arm 110 is connected to a rear end portion 131B of a base portion 130, which will be described later, and the other end of the holding arm 110 is connected to a rear frame 141B of the holding portion 140, which will be described later. The dimension of the holding arm 110 along the X-axis direction is smaller than the dimension of the base portion 130 along the X-axis direction, in plan view.

Here, the shape of the holding arm 110 is not limited to the above. For example, the holding arm 110 may be bent or may be composed of two or more arm portions. One end of the holding arm 110 may be connected to a left end portion 131C or a right end portion 131D of the base portion 130, which will be described later, and the other end of the holding arm 110 may be connected to a front frame 141A, a left frame 141C, or a right frame 141D of the holding portion 140, which will be described later.

The vibrating portion 120 is held so that the vibrating portion 120 can vibrate in a vibration space provided between the lower lid 20 and the upper lid 30. The vibrating portion 120 is provided inside the holding portion 140 in plan view. A space is formed between the vibrating portion 120 and the holding portion 140 with a predetermined interval. The vibrating portion 120 expands along the XY plane during non-vibration (in a state that no voltage is applied), and bends and vibrates in the Z-axis direction during vibration (in a state that a voltage is applied). That is, the main vibration of the vibrating portion 120 is the out-of-plane bending vibration mode.

The vibrating portion 120 includes the base portion 130 and four vibrating arms 135A, 135B, 135C, and 135D (hereinafter, also collectively referred to as the “vibrating arm 135”). Here, the number of vibrating arms is not limited to four, but may be set to an arbitrary number which is one or greater. In the present embodiment, the vibrating portion 120 and the base portion 130 are integrally formed.

The base portion 130 includes a front end portion 131A, the rear end portion 131B, the left end portion 131C, and the right end portion 131D. Each of the front end portion 131A, the rear end portion 131B, the left end portion 131C, and the right end portion 131D is a part of the outer edge portion of the base portion 130. The front end portion 131A is an end portion which extends in the X-axis direction on the side having the vibrating arms 135A to 135D. The rear end portion 131B is an end portion which extends in the X-axis direction on the side opposite to the vibrating arms 135A to 135D. The left end portion 131C is an end portion which extends in the Y-axis direction on the vibrating arm 135A side when viewed from the vibrating arm 135D. The right end portion 131D is an end portion which extends in the Y-axis direction on the vibrating arm 135D side when viewed from the vibrating arm 135A. The vibrating arms 135A to 135D are connected to the front end portion 131A.

The shape of the base portion 130 in plan view is a substantially rectangular shape, with the front end portion 131A and the rear end portion 131B as long sides and the left end portion 131C and the right end portion 131D as short sides. The virtual plane P is defined along a perpendicular bisector of each of the front end portion 131A and the rear end portion 131B. The base portion 130 is not limited to the above structure as long as the base portion 130 has a structure substantially plane-symmetrical to the virtual plane P. For example, the base portion 130 may have a trapezoidal shape in which one of the front end portion 131A and the rear end portion 131B is longer than the other. Further, at least one of the front end portion 131A, the rear end portion 131B, the left end portion 131C, and the right end portion 131D may be bent.

The base portion length, which is the maximum distance in the Y-axis direction between the front end portion 131A and the rear end portion 131B is, for example, approximately 35 μm. Further, the base portion width, which is the maximum distance in the X-axis direction between the left end portion 131C and the right end portion 131D, is, for example, approximately 265 μm. In the configuration example illustrated in FIG. 3, the base portion length corresponds to the length of the left end portion 131C or the right end portion 131D, and the base portion width corresponds to the width of the front end portion 131A or the rear end portion 131B.

The vibrating arms 135A to 135D each extend in the Y-axis direction, and are aligned in this order at predetermined intervals in the X-axis direction. The vibrating arms 135A to 135D have fixed ends, which are connected to the front end portion 131A of the base portion 130, and open ends, which are the farthest from the base portion 130. Each of the vibrating arms 135A to 135D has a weight portion G, which is provided on the side having the open end where the displacement is relatively large in the vibrating portion 120, and an arm portion H, which connects the base portion 130 and the weight portion G with each other. The virtual plane P is positioned between the vibrating arm 135B and the vibrating arm 135C.

Among the four vibrating arms 135A to 135D, the vibrating arms 135A and 135D are outer vibrating arms, which are arranged on the outer side portions in the X-axis direction, and the vibrating arms 135B and 135C are inner vibrating arms, which are arranged on the inner side portions in the X-axis direction. With respect to the virtual plane P, the inner vibrating arm 135B and the inner vibrating arm 135C are symmetrical with each other, and the outer vibrating arm 135A and the outer vibrating arm 135D are symmetrical with each other.

Respective shapes and sizes of the vibrating arms 135A to 135D are substantially the same as each other. The length of each of the vibrating arms 135A to 135D in the Y-axis direction is, for example, approximately 450 μm. For example, the length of the arm portion H in the Y-axis direction is approximately 300 μm, and the width of the arm portion H in the X-axis direction is approximately 50 μm. For example, the length of the weight portion G in the Y-axis direction is approximately 150 μm, and the width of the weight portion G in the X-axis direction is approximately 70 μm. The weight per unit length of the vibrating arm 135 is larger on the open end side than the fixed end side because of the formation of the weight portion G. Thus, each of the vibrating arms 135 has the weight portion G on the open end side, which can increase the amplitude of vertical vibration in the vibrating arm 135.

The holding portion 140 is a portion for holding the vibrating portion 120 in the vibration space which is formed by the lower lid 20 and the upper lid 30. The holding portion 140, for example, surrounds the vibrating portion 120 in a frame shape in plan view. In the example illustrated in FIG. 3, the holding portion 140 includes the front frame 141A, the rear frame 141B, the left frame 141C, and the right frame 141D. Each of the front frame 141A, the rear frame 141B, the left frame 141C, and the right frame 141D is a part of a substantially-rectangular frame body surrounding the vibrating portion 120. Specifically, the front frame 141A is a portion which extends in the X-axis direction on the vibrating arm 135 side when viewed from the base portion 130. The rear frame 141B is a portion which extends in the X-axis direction on the base portion 130 side when viewed from the vibrating arm 135. The left frame 141C is a portion which extends in the Y-axis direction on the vibrating arm 135A side when viewed from the vibrating arm 135D. The right frame 141D is a portion which extends in the Y-axis direction on the vibrating arm 135D side when viewed from the vibrating arm 135A. Each of the front frame 141A and the rear frame 141B is bisected by the virtual plane P.

Respective ends of the left frame 141C are connected to one end of the front frame 141A and one end of the rear frame 141B. Respective ends of the right frame 141D are connected to the other end of the front frame 141A and the other end of the rear frame 141B. The front frame 141A and the rear frame 141B are opposed to each other across the vibrating portion 120 in the Y-axis direction. The left frame 141C and the right frame 141D are opposed to each other across the vibrating portion 120 in the X-axis direction.

The lower lid 20 is a part of a package structure surrounding the vibrating portion 120 of the resonator 10. The lower lid 20 is directly bonded to the lower surface of the resonator 10. The lower lid 20 includes a bottom plate 22, which has a main surface expanding along the XY plane to be in a rectangular flat plate shape, and a side wall 23, which extends from a circumferential portion of the bottom plate 22 toward the upper lid 30. The side wall 23 is bonded to the holding portion 140 of the resonator 10. In the lower lid 20, a cavity 21 surrounded by the bottom plate 22 and the side wall 23 is formed on the side facing the vibrating portion 120 of the resonator 10. The cavity 21 is a rectangular parallelepiped cavity opening upward.

The upper lid 30 is a part of a package structure surrounding the vibrating portion 120 of the resonator 10. The upper lid 30 is bonded to the upper surface of the resonator 10 with the bonding portion 60 interposed therebetween. The upper lid 30 includes a bottom plate 32, which has a main surface expanding along the XY plane to be in a rectangular flat plate shape, and a side wall 33, which extends from a circumferential portion of the bottom plate 32 toward the lower lid 20. The side wall 33 is bonded to the holding portion 140 of the resonator 10. In the upper lid 30, a cavity 31 surrounded by the bottom plate 32 and the side wall 33 is formed on the side facing the vibrating portion 120 of the resonator 10. The cavity 31 is a rectangular parallelepiped cavity opening downward. The cavity 21 and the cavity 31 face each other with the vibrating portion 120 of the resonator 10 interposed therebetween, forming a vibration space of the package structure.

The bonding portion 60 bonds the MEMS substrate 50 and the upper lid 30 to each other, and air-tightly seals the vibration space formed between the lower lid 20 and the upper lid 30. The bonding portion 60 is provided between the holding portion 140 of the resonator 10 and the side wall 33 of the upper lid 30. The bonding portion 60 is formed in a frame shape surrounding the vibrating portion 120 of the resonator 10 in plan view.

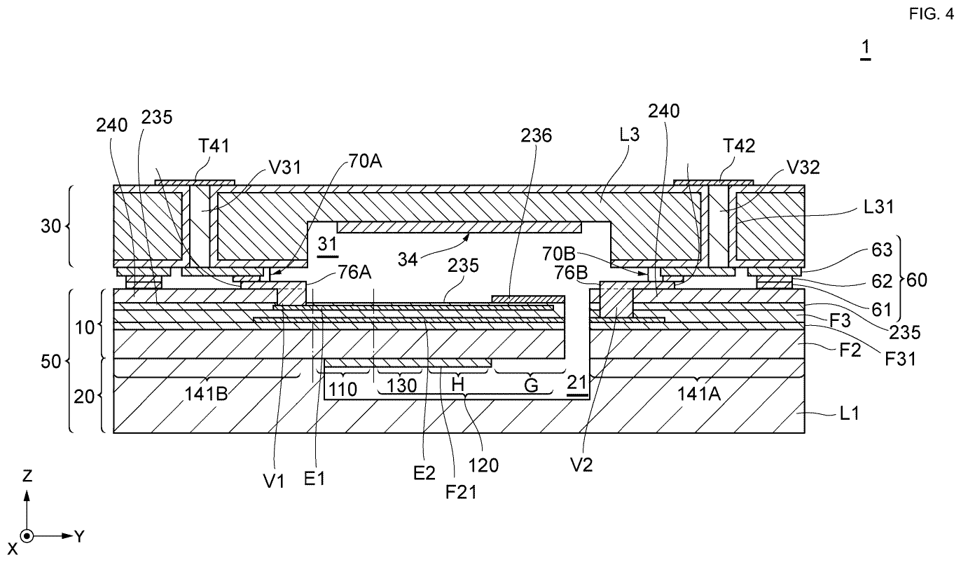

A laminating structure of the resonance device 1 according to the first embodiment of the present disclosure will now be described with reference to FIG. 4. FIG. 4 is a sectional view schematically illustrating the configuration of the resonance device according to the first embodiment. This drawing is the sectional view schematically illustrating the configuration of a section, taken along the IV-IV line, of the resonance device 1 illustrated in FIG. 1 to FIG. 3.

The resonator 10 is held between the lower lid 20 and the upper lid 30. The resonator 10, the lower lid 20, and the upper lid 30 are each formed using a silicon (Si) substrate.

The holding arm 110, vibrating portion 120, and holding portion 140 of the resonator 10 are integrally formed by the same process. The resonator 10 includes a silicon oxide film F21, a silicon substrate F2, an insulating film F31, a metal film E2, a piezoelectric film F3, a metal film E1, a protection film 235, a frequency adjustment film 236, and a parasitic capacitance reduction film 240. The resonator 10 is formed by patterning through removal processing of a multilayer body composed of the silicon substrate F2, the metal film E2, the piezoelectric film F3, the metal film E1, the protection film 235, and the like. The removal processing is, for example, dry etching in which an argon (Ar) ion beam is radiated.

The silicon oxide film F21 is provided on a side, facing the lower lid 20, of the resonator 10. The silicon oxide film F21 is provided on the base portion 130 and the arm portion H in the vibrating portion 120, and also provided on the holding arm 110. The silicon oxide film F21 is separated from the weight portion G in the vibrating portion 120, and also separated from the holding portion 140. The silicon oxide film F21 is provided in a region surrounded by the holding portion 140 and outside the weight portion G in plan view. The silicon oxide film F21 is provided on the lower surface of the silicon substrate F2 in a region facing the cavity 21 of the lower lid 20 in the Z-axis direction, so as to not overlap the weight portion G, which is an example of a tip region. The silicon oxide film F21 is made, for example, of silicon oxide containing SiO₂ and the like. The silicon oxide film F21 functions as a temperature characteristics correction layer that reduces a temperature coefficient of a resonant frequency of the resonator 10, that is, the rate of change of the resonant frequency per unit temperature, at least in the vicinity of room temperature.

Here, the silicon oxide film F21 may be provided so as to not overlap the holding arm 110 and the base portion 130 as long as the silicon oxide film F21 is provided on at least the arm portion H of the vibrating portion 120. However, the silicon oxide film F21 is preferably provided on the base portion 130 as well as the arm portion H of the vibrating portion 120 and more preferably provided also on the holding arm 110.

The silicon substrate F2 is provided on a side, facing a silicon substrate L1 of the lower lid 20, of the resonator 10. The silicon substrate F2 is provided on the entire surface of the resonator 10 in plan view. That is, the silicon substrate F2 is provided on the holding arm 110, the base portion 130 and the vibrating arm 135 of the vibrating portion 120, and the holding portion 140. The silicon substrate F2 is made, for example, of a degenerate n-type silicon (Si) semiconductor containing phosphorus (P), arsenic (As), antimony (Sb), or the like as an n-type dopant. The resistance value of the degenerate silicon (Si) used for the silicon substrate F2 is, for example, less than 16 mΩ·cm, and more preferably 1.2 mΩ·cm or less. The thickness of the silicon substrate F2 is, for example, approximately 6 μm. The silicon substrate F2 is, for example, monocrystalline silicon, but may also be polycrystalline silicon or amorphous silicon. The silicon substrate F2 corresponds to an example of a “silicon film” according to the present disclosure.

The insulating film F31 is laminated on the silicon substrate F2, the metal film E2 is laminated on the insulating film F31, the piezoelectric film F3 is laminated on the metal film E2, and the metal film E1 is laminated on the piezoelectric film F3.

The insulating film F31 insulates the silicon substrate F2 and the metal film E2 from each other. The insulating film F31 is made, for example, of the same material as that of the piezoelectric film F3.

Each of the metal films E2 and E1 has a portion functioning as an excitation electrode that excites the vibrating arms 135A to 135D, and a portion functioning as an extended electrode that electrically connects the excitation electrode to an external power source. The respective portions functioning as an excitation electrode in the metal films E2 and E1 face each other at the arm portions H of the vibrating arms 135A to 135D with the piezoelectric film F3 interposed therebetween. The portions functioning as an extended electrode in the metal films E2 and E1 are, for example, derived from the base portion 130 through the holding arm 110 to the holding portion 140. The metal film E2 is electrically continuous throughout the resonator 10. In the metal film E1, portions which are formed on the outer vibrating arms 135A and 135D and portions which are formed on the inner vibrating arms 135B and 135C are electrically separated from each other. The metal film E2 corresponds to a lower electrode, and the metal film E1 corresponds to an upper electrode. The thickness of each of the metal films E2 and E1 is, for example, approximately from 0.1 μm to 0.2 μm inclusive. The metal films E2 and E1 are patterned into an excitation electrode, an extended electrode, and the like by removal processing such as etching after film deposition. The metal films E2 and E1 are made, for example, of a metal material whose crystal structure is a body-centered cubic structure. Specifically, the metal films E2 and E1 are made of molybdenum (Mo), tungsten (W), or the like.

The piezoelectric film F3 is a thin film which is made of a piezoelectric material that converts electrical energy into mechanical energy and vice versa. The piezoelectric film F3 expands and contracts in the Y-axis direction of the in-plane direction of the XY plane in response to an electric field applied by the metal films E2 and E1. This expansion and contraction of the piezoelectric film F3 causes the vibrating arm 135 to bend and displace its open end toward the bottom plate 22 of the lower lid 20 or the bottom plate 32 of the upper lid 30. Alternating voltages having mutually opposite phases are applied to the upper electrodes of the outer vibrating arms 135A and 135D and the upper electrodes of the inner vibrating arms 135B and 135C. As a result, the outer vibrating arms 135A and 135D and the inner vibrating arms 135B and 135C vibrate in opposite phases. For example, when the open ends of the outer vibrating arms 135A and 135D are displaced toward the lower lid 20, the open ends of the inner vibrating arms 135B and 135C are displaced toward the upper lid 30. Such opposite-phase vibration generates a torsional moment about a rotation axis extending in the Y-axis direction, in the vibrating portion 120. The base portion 130 bends in accordance with this torsional moment, which displaces the left end potion 131C and the right end portion 131D toward the lower lid 20 or the upper lid 30.

The piezoelectric film F3 is made of a material having a crystal structure of wurtzite-type hexagonal crystal structure, in which the main component can be, for example, a nitride or oxide such as aluminum nitride (AlN), scandium aluminum nitride (SCAlN), zinc oxide (ZnO), gallium nitride (GaN), and indium nitride (InN). Here, scandium aluminum nitride is obtained by replacing a portion of the aluminum in aluminum nitride with scandium, and a portion of the aluminum may be replaced by two elements such as magnesium (Mg) and niobium (Nb), or magnesium (Mg) and zirconium (Zr), instead of scandium. The thickness of the piezoelectric film F3 is, for example, approximately 1 μm, but may be approximately from 0.2 μm to 2 μm inclusive.

The protection film 235 is laminated on the metal film E1. The protection film 235 protects, for example, the metal film E1 from oxidation. The material of the protection film 235 is, for example, an oxide, nitride, or oxynitride containing aluminum (Al), tantalum (Ta), zinc (Zn), gallium (Ga), indium (In), or silicon (Si).

The frequency adjustment film 236 is laminated on the protection film 235 in the weight portion G. The frequency adjustment film 236 adjusts the frequency of the resonator 10 when being etched. The frequency adjustment film 236 is preferably made of a material having a faster rate of mass reduction caused by etching than that of the protection film 235. The rate of mass reduction is expressed by a product of etching rate and density. Etching rate is the thickness removed per unit time. The etching rate magnitude relationship between the protection film 235 and the frequency adjustment film 236 is arbitrary as long as the relationship in the rate of mass reduction is as described above. The frequency adjustment film 236 also functions as a mass-adding film that increases the weight per unit length of the weight portion G. From the perspective of the mass-adding film, the frequency adjustment film 236 is preferably made of a material with a high specific gravity. From the above two perspectives, the material of the frequency adjustment film 236 is preferably a metal material such as molybdenum (Mo), tungsten (W), gold (Au), platinum (Pt), nickel (Ni), and titanium (Ti).

The parasitic capacitance reduction film 240 is laminated on the protection film 235 in the holding portion 140. The parasitic capacitance reduction film 240 reduces parasitic capacitance formed between pieces of internal wiring of the resonator 10. The parasitic capacitance reduction film 240 has a function as an insulating layer working when pieces of wiring of different potentials cross, and a function as a standoff for expanding the vibration space. The parasitic capacitance reduction film 240 is made, for example, of tetraethyl orthosilicate (TEOS). The thickness of the parasitic capacitance reduction film 240 is, for example, approximately 1 μm.

On the parasitic capacitance reduction film 240 in the holding portion 140, contact electrodes 76A and 76B are provided. The contact electrode 76A is electrically connected to the metal film E1 via a through-electrode V1 which penetrates through the protection film 235 and the parasitic capacitance reduction film 240. The contact electrode 76B is electrically connected to the metal film E2 via a through-electrode V2 which penetrates through the piezoelectric film F3, the protection film 235, and the parasitic capacitance reduction film 240. The contact electrodes 76A and 76B are made, for example, of a metal material such as aluminum (Al), germanium (Ge), gold (Au), and tin (Sn).

The bottom plate 22 and the side wall 23 of the lower lid 20 are integrally formed by the silicon substrate L1. The silicon substrate L1 is made of non-degenerate silicon semiconductor, and has a resistivity of, for example, 10 Ω·cm or higher. The maximum thickness of the silicon substrate L1 is larger than the thickness of the silicon substrate F2 and is, for example, approximately 150 μm. The depth of the cavity 21 is, for example, approximately 50 μm. The silicon substrate L1 corresponds to an example of a “first silicon substrate” according to the present disclosure.

The silicon substrate L1 forms the surface of the lower lid 20. Accordingly, the silicon substrate L1 of the lower lid 20 and the silicon substrate F2 of the resonator 10 are in contact with each other at the bonding portion between the side wall 23 of the lower lid 20 and the holding portion 140 of the resonator 10. In other words, the silicon substrate L1 and the silicon substrate F2 are directly bonded to each other in the entire circumferential region surrounding the vibration space of the resonator 10 in plan view.

The bottom plate 32 and the side wall 33 of the upper lid 30 are integrally formed by a silicon substrate L3. On the surface of the silicon substrate L3, a silicon oxide film L31 is provided. Specifically, the silicon oxide film L31 is provided on a region between the silicon substrate L3 and through-electrodes V31 and V32, which will be described later, a region between the silicon substrate L3 and pieces of connection wiring 70A and 70B, which will be described later, and a region between the silicon substrate L3 and terminals T41 and T42, which will be described later. The silicon oxide film L31 inhibits short circuits of electrodes and the like occurring via the silicon substrate L3. Here, electrodes and the like, which cause short circuits, are not provided on the inner wall of the cavity 31 on the surface of the silicon substrate L3. Therefore, the silicon substrate L3 may be exposed on the inner wall of the cavity 31. The silicon oxide film L31 is formed, for example, by thermal oxidation of the silicon substrate L3 or chemical vapor deposition (CVD). For example, the thickness of the upper lid 30 is approximately 150 μm, and the depth of the cavity 31 is approximately 50 μm. The silicon substrate L3 corresponds to an example of a “second silicon substrate” according to the present disclosure.

On the lower surface of the bottom plate 32 of the upper lid 30, a metal film 34 is provided. The metal film 34 is a getter that improves the degree of vacuum by absorbing gas in the vibration space formed by the cavities 21 and 31, and stores, for example, hydrogen gas. The metal film 34 contains, for example, titanium (Ti), zirconium (Zr), vanadium (V), niobium (Nb), tantalum (Ta), or an alloy containing at least one of these. The metal film 34 may contain an oxide of an alkali metal or an oxide of an alkaline earth metal.

The through-electrodes V31 and V32 are provided in the upper lid 30. The through-electrodes V31 and V32 are provided inside through holes which penetrate through the side wall 33 in the Z-axis direction. The through-electrodes V31 and V32 are surrounded by the silicon oxide film L31 and insulated from each other. The through-electrodes V31 and V32 are formed by filling the through holes with polycrystalline silicon (Poly-Si), copper (Cu), or gold (Au), for example.

The pieces of connection wiring 70A and 70B are provided on the lower surface of the upper lid 30, and the terminals T41 and T42 are provided on the upper surface of the upper lid 30. The connection wiring 70A is connected to a lower end portion of the through-electrode V31, and the terminal T41 is connected to an upper end portion of the through-electrode V31. The connection wiring 70B is connected to a lower end portion of the through-electrode V32, and the terminal T42 is connected to an upper end portion of the through-electrode V32. The connection wiring 70A is a connection terminal that electrically connects the through-electrode V31 with the contact electrode 76A, and the terminal T41 is a mounting terminal that electrically connects the metal film E1 of the outer vibrating arms 135A and 135D to the external power source. The connection wiring 70B is a connection terminal that electrically connects the through-electrode V32 with the contact electrode 76B, and the terminal T42 is a mounting terminal that grounds the metal film E2. The connection wiring 70B is a connection terminal that electrically connects the through-electrode V32 with the contact electrode 76B, and the terminal T42 is a mounting terminal that electrically connects the metal film E2 of the outer vibrating arms 135A and 135D to the external power source. Although not shown, the upper lid 30 is further provided with through-electrodes, pieces of connection wiring, and terminals that are electrically connected to the metal film E1 of the inner vibrating arms 135B and 135C.

A plurality of pieces of connection wiring including the pieces of connection wiring 70A and 70B are electrically insulated from each other by the silicon oxide film L31. A plurality of terminals including the terminals T41 and T42 are also electrically insulated from each other by the silicon oxide film L31. The plurality of pieces of connection wiring and the plurality of terminals are formed by plating nickel (Ni), gold (Au), silver (Ag), copper (Cu), or the like on a metallized layer (underlying layer) of chrome (Cr), tungsten (W), nickel (Ni), or the like, for example. The plurality of terminals may include dummy terminals that are electrically insulated from the resonator 10 for the purpose of adjusting the balance of parasitic capacitance and mechanical strength.

The bonding portion 60 bonds the side wall 33 of the upper lid 30 with the holding portion 140 of the resonator 10. The bonding portion 60 includes, for example, a silicon oxide film 61, a first metal film 62, and a second metal film 63. The MEMS substrate 50 and the upper lid 30 are bonded to each other by eutectic bonding of the first metal film 62 and the second metal film 63.

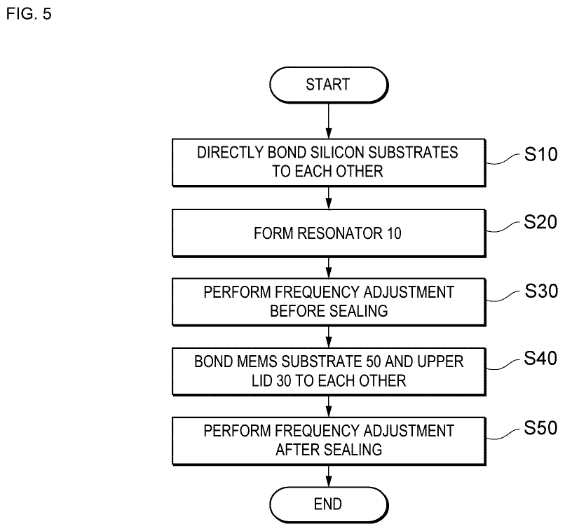

A manufacturing method for the resonance device 1 according to the first embodiment of the present disclosure will now be described with reference to FIG. 5. FIG. 5 is a flowchart showing the resonance device 1 manufacturing method according to an embodiment of the present disclosure.

First, silicon substrates are directly bonded to each other (S10). Two plate-like silicon substrates L1 and F2 are first prepared. Then, one side of each of the silicon substrates L1 and F2 is mirror-polished. The cavity 21 is subsequently formed on the mirror-polished side of the silicon substrate L1. Next, the mirror surfaces of the silicon substrates L1 and F2 are cleaned and hydrophilic-treated using pure water or the like. The hydrophilic-treated mirror surfaces are subsequently overlapped with each other, and the silicon substrate L1 and the silicon substrate F2 are heated. Here, the mirror-polishing of the silicon substrate L1 may be performed after the cavity 21 is formed.

Here, direct bonding of silicon to silicon requires higher planarity on bonding surfaces than bonding with a silicon oxide film interposed therebetween. The mirror-polishing process in step S10 may therefore include, for example, twice or more times of polishing process. The surface roughness Ra of the mirror surface of each of the silicon substrates L1 and F2 is preferably 1 nm or less, more preferably 0.5 nm or less, and still more preferably 0.3 nm or less.

Next, the resonator 10 is formed (S20). The insulating film F31, metal film E2, piezoelectric film F3, metal film E1, protection film 235, and so forth are deposited in sequence on the silicon substrate F2, which is directly bonded to the silicon substrate L1, and the vibrating portion 120, holding portion 140, and holding arm 110 of the resonator 10 are patterned by etching. The resonator 10 bonded to the lower lid 20 is thus formed, and the MEMS substrate 50 is accordingly prepared.

Then, frequency adjustment before sealing is performed (S30). The mass-adding film is trimmed while monitoring the frequency of the resonator 10 so as to adjust the frequency of the resonator 10.

Next, the MEMS substrate 50 and the upper lid 30 are bonded to each other (S40). The MEMS substrate 50 and the upper lid 30 are bonded by the arm portion H in a vacuum environment.

Subsequently, frequency adjustment after sealing is performed (S50). An electric field stronger than an electric field, which is applied in normal use as the resonance device 1, is applied between the metal film E1 and the metal film E2 of the resonator 10 so as to increase the amplitude of the resonator 10 (hereinafter, also referred to as “overexcitation”). The tip of the vibrating arm 135 of the overexcited resonator 10 collides with the inner wall of the lower lid 20, and the tip portion of the vibrating arm 135 is abraded. Thus, the frequency of the resonator 10 is adjusted by change of the mass of the vibrating arm 135.

As described above, the silicon substrate L1 and the silicon substrate F2 are directly bonded to each other in the entire circumferential region surrounding the vibration space of the resonator 10 in plan view.

The silicon substrate L1 and the silicon substrate F2 are thus directly bonded to each other without an interlayer silicon oxide film being interposed therebetween, which serves as a helium ingress path, and accordingly, ingress of helium gas from a portion between the silicon substrate L1 and the silicon substrate F2 can be suppressed. Therefore, decrease in the degree of vacuum in the vibration space is suppressed, and reliability is improved. In addition, the resonance device 1 has similar air-tightness to helium gas and nitrogen gas and accordingly, the air-tightness test can be performed using inexpensive nitrogen gas instead of using helium gas. Therefore, it is possible to inexpensively screen out products with air-tightness defects compared to, for example, defective molding of a blocking member in a configuration where the air-tightness against helium gas differs from the air-tightness against nitrogen gas, that is, a configuration where ingress of helium gas is blocked by a blocking member that penetrates through an interlayer silicon oxide film provided between silicon substrates.

Furthermore, the silicon oxide film F21 is provided in a manner avoiding the holding portion 140. Therefore, the frequency-temperature characteristics of the resonator 10 can be compensated without forming an ingress path for helium gas between the silicon substrate L1 and the silicon substrate F2.

In addition, the silicon oxide film F21 is provided so as to not overlap the weight portion G of the vibrating arm 135. Therefore, the silicon substrate L1 and the silicon substrate F2 collide with each other when the frequency is adjusted by causing the vibrating arm 135 to collide with the lower lid 20 through overexcitation to abrade it. Silicon is more easily abraded by low-velocity collisions than a silicon oxide. For this reason, when the cavity 21 is formed shallow, it is possible to reduce dust generated from the lower lid 20 abraded by the time when the frequency adjustment is completed through abrasion of the vibrating arm 135, compared to a configuration in which a silicon oxide film is provided at a tip region of the vibrating portion. Thus, the resonance device 1 can be formed lower in height.

### Second Embodiment

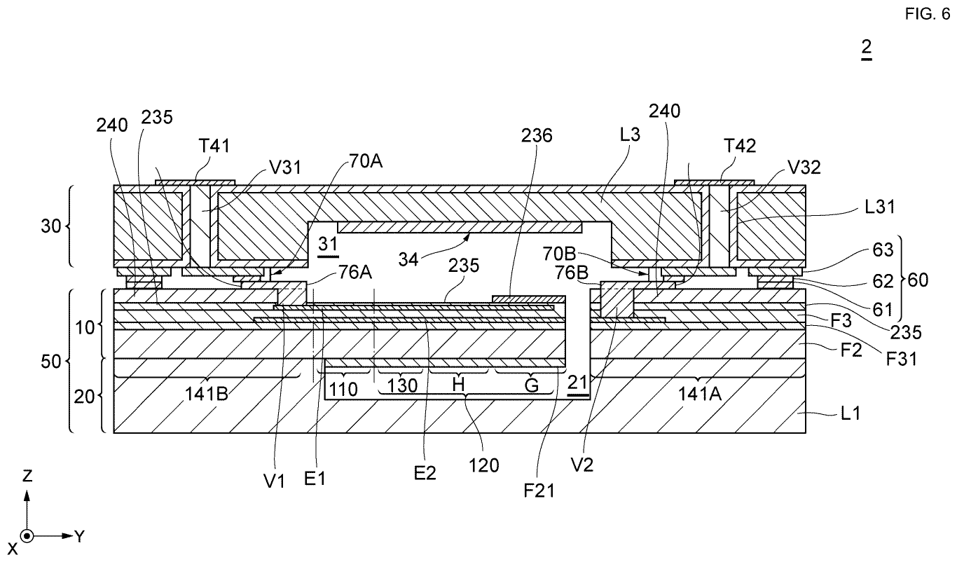

A configuration of a resonance device 2 according to a second embodiment will now be described with reference to FIG. 6. FIG. 6 is a sectional view schematically illustrating the configuration of the resonance device according to the second embodiment.

In the second embodiment, the forming region of the silicon oxide film F21 is different from that of the first embodiment. Specifically, the silicon oxide film F21 is provided on the lower surfaces of the holding arm 110, base portion 130, and arm portion H of the resonator 10 in the first embodiment, while the silicon oxide film F21 is further provided on the lower surface of the weight portion G of the resonator 10 in the present embodiment. Thus, the resonator 10 has the silicon oxide film F21 provided on the entire surface of the vibrating portion 120 on the side facing the silicon substrate L1. According to this, by forming the silicon oxide film F21 on the lower surfaces of the holding arm 110, base portion 130, weight portion G, and arm portion H of the resonator 10, which have a large influence on the frequency-temperature characteristics of a vibrator, the thickness of the silicon oxide film F21 can be optimized to obtain favorable frequency-temperature characteristics.

### Third Embodiment

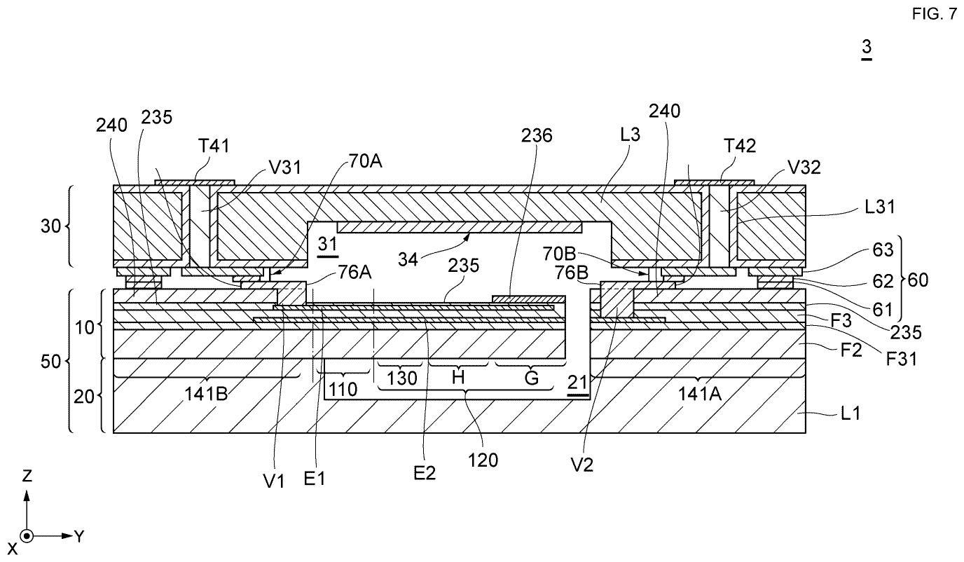

A configuration of a resonance device 3 according to a third embodiment will now be described with reference to FIG. 7. FIG. 7 is a sectional view schematically illustrating the configuration of the resonance device according to the third embodiment.

The third embodiment is different from the first embodiment in that the silicon oxide film F21 is not provided. That is, in the present embodiment, the resonator 10 has the silicon substrate F2 provided on the side facing the lower lid 20. Specifically, the silicon substrate F2 is provided as the outermost layer on the lower surfaces of the holding arm 110 and vibrating portion 120 of the resonator 10. This configuration does not require the formation of the silicon oxide film F21, being able to simplify the manufacturing process.

### Fourth Embodiment

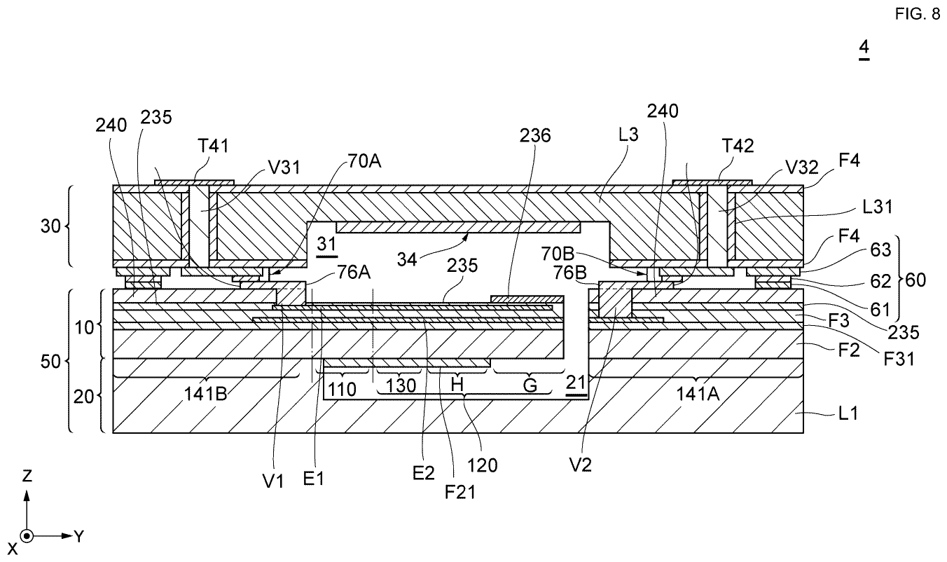

A configuration of a resonance device 4 according to a fourth embodiment will now be described with reference to FIG. 8. FIG. 8 is a sectional view schematically illustrating the configuration of the resonance device according to the fourth embodiment.

In the fourth embodiment, different from the first embodiment in which the silicon oxide film L31 is formed on the upper surface and lower surface of the upper lid 30, a silicon nitride film F4 is formed in place of the silicon oxide film L31. That is, in the present embodiment, the upper lid 30 has the silicon nitride film F4 which is provided on at least one of the surface of the silicon substrate L3 facing the resonator 10 and a surface opposite to the surface facing the resonator 10. The silicon nitride film F4 is thus provided in place of the silicon oxide film L31, being able to suppress the ingress of helium gas from the outside through the silicon oxide film L31, which is provided on the upper surface or the lower surface of the upper lid 30, into the vibration space. Accordingly, helium leakage can be suppressed even more effectively. In addition, the silicon nitride film F4 is formed on the wafer surface and therefore, formation defects can be easily screened out by visual inspection. Thus, a resonator which is resistant to helium leakage can be provided without performing conventional high-cost screening inspection. The silicon nitride film F4 is formed on both of the upper surface and the lower surface of the upper lid 30 in the present embodiment, but not limited to this. The silicon nitride film F4 may be formed at least one of the upper surface and the lower surface.

### Fifth Embodiment

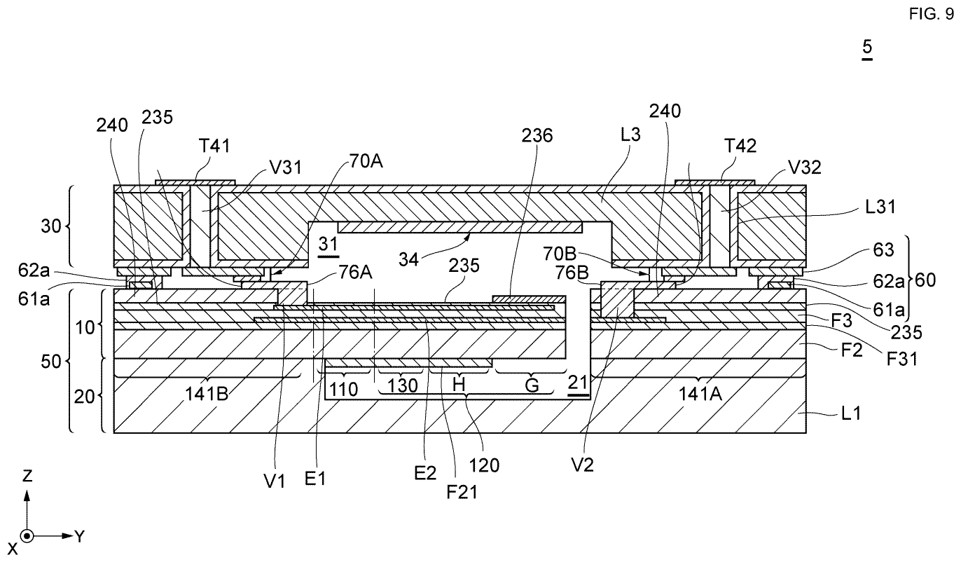

A configuration of a resonance device 5 according to a fifth embodiment will now be described with reference to FIG. 9. FIG. 9 is a sectional view schematically illustrating the configuration of the resonance device according to the fifth embodiment.

In the fifth embodiment, the aspect of the bonding portion 60 is different from that of the first embodiment. Specifically, the bonding portion 60 includes a silicon oxide film 61a, which is provided on the side of the MEMS substrate 50, a first metal film 62a, which covers the side wall of the silicon oxide film 61a, and the second metal film 63, which is laminated on the second metal film 62a. The first metal film 62a thus covers the side wall of the silicon oxide film 61a, being able to effectively suppress the ingress of helium gas from the outside into the vibration space.

### Sixth Embodiment

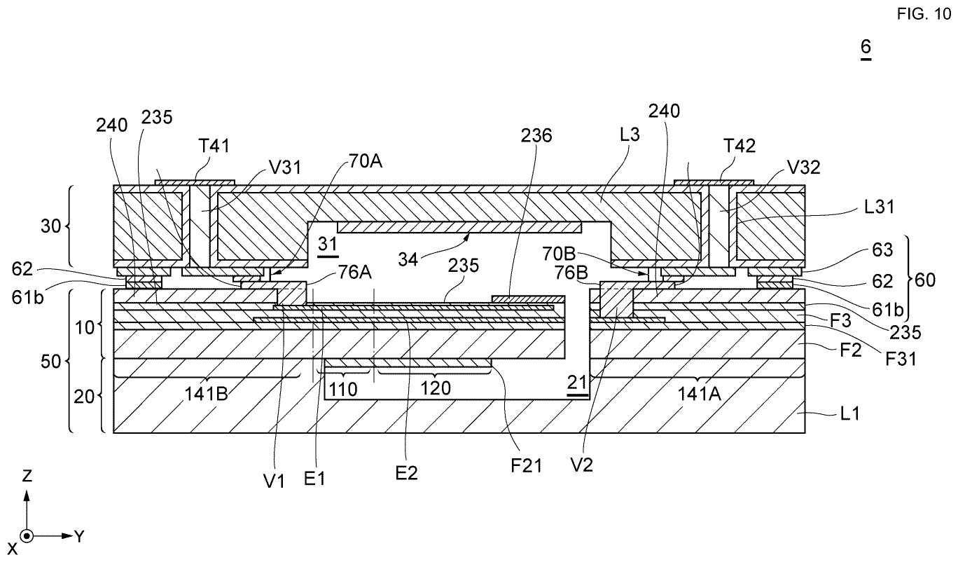

A configuration of a resonance device 6 according to a sixth embodiment will now be described with reference to FIG. 10. FIG. 10 is a sectional view schematically illustrating the configuration of the resonance device according to the sixth embodiment.

In the sixth embodiment, the aspect of the bonding portion 60 is different from that of the first embodiment and the fifth embodiment. Specifically, the bonding portion 60 includes a silicon nitride film 61b, which is provided on the side of the MEMS substrate 50, the first metal film 62, which is laminated on the silicon nitride film 61b, and the second metal film 63, which is laminated on the first metal film 62. The first metal film 62 and the second metal film 63 are provided between the resonator 10 and the upper lid 30. The silicon nitride film 61b is thus employed instead of the silicon oxide film in the bonding portion 60, being able to more effectively suppress the ingress of helium gas from the outside into the vibration space.

### Seventh Embodiment

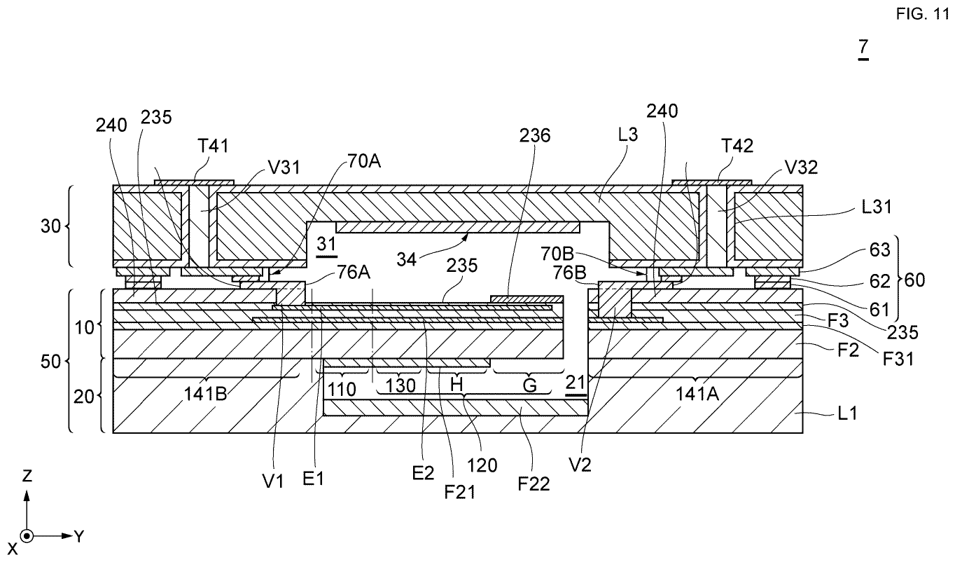

A configuration of a resonance device 7 according to a seventh embodiment will now be described with reference to FIG. 11. FIG. 11 is a sectional view schematically illustrating the configuration of the resonance device according to the seventh embodiment.

The seventh embodiment is different from the first embodiment in that a silicon oxide film F22 is provided on the silicon substrate L1 in the seventh embodiment. Specifically, the silicon oxide film F22 is provided on the bottom surface of the bottom plate 22 of the silicon substrate L1 in the present embodiment. This makes it possible to suppress cutting waste generated from the lower lid 20 side during overexcitation processing in the frequency adjustment process.

Part or all of embodiments of the present disclosure will be appended below. However, note that the present disclosure is not limited to the following additional notes.

According to an aspect of the present disclosure, there is provided a resonance device including: a first substrate which includes a first silicon substrate and a resonator; a second substrate which is arranged on a side on which the resonator in the first substrate is provided; and a bonding portion which bonds the first substrate and the second substrate to each other so as to seal a vibration space of the resonator, in which the resonator has a silicon film which is provided on a surface on a side facing the first silicon substrate, and the silicon film is directly bonded to the first silicon substrate in an entire circumferential region surrounding the vibration space in plan view of the first substrate.

As an aspect, a cavity constituting the vibration space may be formed in the first silicon substrate, and the resonator may include a vibrating portion which is positioned inside the vibration space, a holding portion which is provided around the vibrating portion in plan view of the first substrate, and a holding arm which connects the holding portion and the vibrating portion with each other.

As an aspect, the silicon film may be provided on an entire surface of the vibrating portion on a side facing the first silicon substrate.

As an aspect, the resonator may have a silicon oxide film provided on a surface of the vibrating portion on a side facing the first silicon substrate.

As an aspect, the vibrating portion may include a base portion which is connected to the holding arm, and a plurality of vibrating arms which are connected to the base portion, and the silicon oxide film may be provided so as to not overlap a tip region in the plurality of vibrating arms, the tip region being opposite to the base portion in plan view of the first substrate.

As an aspect, the second substrate may include a second silicon substrate, and a silicon nitride film which is provided on at least one surface of a surface facing the resonator and a surface opposite to the surface facing the resonator in the second silicon substrate.

As an aspect, the bonding portion may include a silicon oxide film which is provided on a side of the first substrate, and a metal film which covers a side wall of the silicon oxide film.

As an aspect, the bonding portion may include a silicon nitride film which is provided on a side of the first substrate, and a metal film which is provided between the silicon nitride film and the second substrate.

As an aspect, a silicon oxide film may be provided on a bottom surface of the cavity of the first silicon substrate.

According to another aspect of the present disclosure, there is provided a resonance device manufacturing method including: forming a first substrate by bonding a first silicon substrate and a resonator to each other; and bonding the first substrate and a second substrate to each other so as to seal a vibration space of the resonator, in which the resonator has a silicon film which is provided on a surface on a side facing the first silicon substrate, the silicon film is provided in an entire circumferential region surrounding the vibration space in plan view of the first substrate, and the forming the first substrate includes directly bonding the silicon film and the first silicon substrate to each other.

As an aspect, the resonance device manufacturing method may further include adjusting a frequency by causing the resonator and the first substrate to collide with each other by applying a voltage to the resonator after bonding the first substrate and the second substrate to each other.

Although the resonator using the out-of-plane bending vibration mode has been described as an example of the resonator according to one embodiment of the present disclosure, the resonator according to the present disclosure is not limited to this. The resonator may be, for example, a piezoelectric vibrating element using a spreading vibration mode, a thickness longitudinal vibration mode, a Lamb wave vibration mode, an in-plane bending vibration mode, or a surface acoustic wave vibration mode. In addition, the resonator may be an electrostatic MEMS element, an electromagnetically driven MEMS element, or a piezo-resistive MEMS element.

The embodiments according to the present disclosure can be appropriately applied, without any particular limitation, to any device that utilizes the frequency characteristics of a vibrator such as a timing device, an RF filter, a duplexer, an ultrasonic transducer, a sound generator, an oscillator, a gyro sensor, an acceleration sensor, and a load sensor, for example.

According to an aspect of the present disclosure, the resonance device and resonance device manufacturing method that can achieve suppression of ingress of helium gas can be provided, as described above.

It should be noted that the embodiments described above are provided for facilitating the understanding of the present disclosure, and are not provided for limiting the interpretation of the present disclosure. The present disclosure can be modified/improved without departing from the spirit thereof, and the present disclosure also includes an equivalent thereof. That is, each embodiment whose design is appropriately changed by those skilled in the art is also included in the scope of the present disclosure as long as the embodiment has the features of the present disclosure. For example, elements included in each embodiment and those arrangement, material, condition, shape, size, and the like are not limited to those exemplified, and can be appropriately changed. Furthermore, the elements provided by each embodiment can be combined to the extent technically possible, and such combinations are also included within the scope of the present disclosure as long as they include the features of the present disclosure.

### REFERENCE SIGNS LIST

1 resonance device
10 resonator
20 lower lid
30 upper lid
50 MEMS substrate
110 holding arm
120 vibrating portion
130 base portion
140 holding portion
G weight portion
H arm portion
F2, L1 silicon substrate
F21 silicon oxide film

1. A resonance device comprising:
a first substrate which includes a first silicon substrate and a resonator;
a second substrate arranged on a side of the resonator opposite to the first silicon substrate; and
a bonding portion bonding the first substrate and the second substrate to each other so as to seal a vibration space of the resonator, wherein
the resonator has a silicon film on a surface thereof facing the first silicon substrate, and
the silicon film is directly bonded to the first silicon substrate in an entire circumferential region surrounding the vibration space in a plan view of the first substrate.

2. The resonance device according to claim 1, wherein
the first silicon substrate defines a cavity of the vibration space, and
the resonator includes a vibrating portion positioned inside the vibration space, a holding portion around the vibrating portion in a plan view of the first substrate, and a holding arm connecting the holding portion and the vibrating portion to each other.

3. The resonance device according to claim 2, wherein the silicon film is on an entire surface of the vibrating portion on a side thereof facing the first silicon substrate.

4. The resonance device according to claim 2, further comprising a silicon oxide film on a surface of the vibrating portion on a side thereof facing the first silicon substrate.

5. The resonance device according to claim 4, wherein
the vibrating portion includes a base portion connected to the holding arm, and a plurality of vibrating arms connected to the base portion, and
the silicon oxide film is provided so as to not overlap a tip region in the plurality of vibrating arms, the tip region being opposite to the base portion in the plan view of the first substrate.

6. The resonance device according to claim 1, wherein the second substrate includes a second silicon substrate, and a silicon nitride film on at least one surface of a surface facing the resonator and a surface opposite to the surface facing the resonator in the second silicon substrate.

7. The resonance device according to claim 1, wherein the bonding portion includes a silicon oxide film on a side of the first substrate, and a metal film which covers a side wall of the silicon oxide film.

8. The resonance device according to claim 1, wherein the bonding portion includes a silicon nitride film on a side of the first substrate, and a metal film between the silicon nitride film and the second substrate.

9. The resonance device according to claim 2, further comprising a silicon oxide film on a bottom surface of the cavity of the first silicon substrate.

10. A resonance device manufacturing method comprising:
forming a first substrate by directly bonding a first silicon substrate and silicon film of a resonator to each other; and
bonding the first substrate and a second substrate to each other so as to seal a vibration space of the resonator, wherein
the silicon film is in an entire circumferential region surrounding the vibration space in a plan view of the first substrate.

11. The resonance device manufacturing method according to claim 10, further comprising:
adjusting a frequency by causing the resonator and the first substrate to collide with each other by applying a voltage to the resonator after bonding the first substrate and the second substrate to each other.

12. The resonance device manufacturing method according to claim 10, wherein
the first silicon substrate defines a cavity of the vibration space, and
the resonator includes a vibrating portion positioned inside the vibration space, a holding portion around the vibrating portion in the plan view of the first substrate, and a holding arm connecting the holding portion and the vibrating portion to each other.

13. The resonance device manufacturing method according to claim 12, wherein the silicon film is on an entire surface of the vibrating portion on a side thereof facing the first silicon substrate.

14. The resonance device manufacturing method according to claim 12, further comprising forming a silicon oxide film on a surface of the vibrating portion on a side thereof facing the first silicon substrate.

15. The resonance device manufacturing method according to claim 14, wherein
the vibrating portion includes a base portion connected to the holding arm, and a plurality of vibrating arms connected to the base portion, and
the silicon oxide film is formed so as to not overlap a tip region in the plurality of vibrating arms, the tip region being opposite to the base portion in the plan view of the first substrate.

16. The resonance device manufacturing method according to claim 10, wherein the second substrate includes a second silicon substrate, and the method further comprises forming a silicon nitride film on at least one surface of a surface facing the resonator and a surface opposite to the surface facing the resonator in the second silicon substrate.

17. The resonance device manufacturing method according to claim 10, wherein the first substrate and the second substrate are bonded to each other using a bonding portion that includes a silicon oxide film on a side of the first substrate, and a metal film which covers a side wall of the silicon oxide film.

18. The resonance device manufacturing method according to claim 10, wherein the first substrate and the second substrate are bonded to each other using a bonding portion that includes a silicon nitride film on a side of the first substrate, and a metal film between the silicon nitride film and the second substrate.

19. The resonance device manufacturing method according to claim 12, further comprising forming a silicon oxide film on a bottom surface of the cavity of the first silicon substrate.
